(19) United States
(12) Patent Application Publication
(10) Pub. No.: US 2008/0099834 A1
(43) Pub. Date: May 1, 2008

(54) Transistor, an inverter and a method of manufacturing the same

(76) Inventor: Josef Willer, Riemerling (DE)

Correspondence Address: EDELL , SHAPIRO & FINNAN , LLC, 1901 RESEARCH BOULEVARD , SUITE 400, ROCKVILLE, MD, 20850, US

(21) Appl. No.: 11/589,303

(22) Filed: Oct. 30, 2006

(51) Int. Cl. H01L 29/94; H01L 21/336

(52) U.S. Cl. 257/330; 438/270; 257/E29.201

(57) ABSTRACT

An inverter which is at least partially formed in a semiconductor substrate includes a first transistor with a first channel and a second transistor with a second channel, wherein each of the first and second transistors is formed as a FinFET with ridge shaped channels. The first and second gate electrodes of the first and second transistors are adjacent to the first and second channels on at least three sides of the corresponding channel. The first gate electrode extends from a top surface of the first channel ridge to a first ridge depth along the first channel, and the second gate electrode extends from a top surface of the second channel ridge to a second ridge depth along the second channel, wherein the first ridge depth is greater than the second ridge depth.

### BACKGROUND

An important semiconductor technology used for the manufacture of ultra-large scale integrated (ULSI) circuits is based on the metal-oxide-semiconductor field effect transistor (MOSFET) technology. Generally, such a MOSFET is formed in a semiconductor substrate which is doped with a certain conductivity type, for example p-doped or n-doped. The MOSFET comprises a source and a drain region, i.e., doped regions which are doped with a complementary conductivity type with respect to the substrate. For example, if the substrate is p-doped, the source and drain regions are n-doped. A channel is formed between the source and drain regions and a gate electrode is disposed adjacent to the channel, the gate electrode being insulated from the channel by a gate insulating material. Depending on the conductivity type of the substrate, the conductivity of the channel is based on the conduction of holes or of electrons, respectively. Accordingly, the transistor in which the substrate is p-doped is referred to as an n-channel MOSFET (NMOS) whereas a transistor which is formed in an n-doped substrate is referred to as a p-channel transistor (PMOS).

In a specific transistor type, the active area in which the source and drain regions as well as the channel are disposed has the form of a ridge comprising a top side and two lateral sides. In such a transistor, the gate electrode encloses the ridge at three sides thereof. This transistor is advantageous because the channel may become fully depleted due to the fact that the channel is enclosed by the gate electrode at three sides thereof. Such a transistor is referred to as a FinFET. Typically in such a FinFET, the width of the transistor corresponds to an extent by which the channel is controlled by the gate electrode in a direction perpendicularly with respect to the direction of current flow. In particular, in such a FinFET the width of the channel corresponds to the width of the top portion of the ridge as well as to the depth of the ridge to which the gate electrode extends.

### SUMMARY

A transistor an inverter and a method of manufacturing a transistor are described herein. An inverter, which is at least partially formed in a semiconductor substrate, comprises a first transistor including: a first source region connected to a power supply, a first drain region connected to an output terminal, a first channel being formed between the first source and drain regions, a first gate electrode adjacent to the first channel, and a first gate insulating layer which is disposed between the first gate electrode and the first channel, a second transistor comprising a second source region connected to a ground, a second drain region connected to the output terminal, a source channel being formed between the second source and drain regions, a second gate electrode adjacent to the channel, and a second gate insulating layer which is disposed between the second gate electrode and the second channel, an input terminal connected to the first and second gate electrodes, wherein each of the first and second transistors are formed as FinFETs, the first and the second channels being ridge shaped, the first and second gate electrode being adjacent to the first and second channels on at least three sides of the corresponding channel, the first gate electrode extending from a top surface of the corresponding ridge to a depth d1 along the first channel and the second gate electrode extending from a top surface of the corresponding ridge to a depth d2 along the second channel, wherein d1>d2.

The above and still further features and advantages of the described devices and method will become apparent upon consideration of the following definitions, descriptions and descriptive figures of specific embodiments thereof, wherein like reference numerals in the various figures are utilized to designate like components. While these descriptions go into specific details of the devices and method, it should be understood that variations may and do exist and would be apparent to those skilled in the art based on the descriptions herein.

### BRIEF DESCRIPTION OF THE DRAWINGS

The accompanying drawings are included to provide a further understanding of the described device and are incorporated in and constitute a part of this specification. The drawings illustrate the embodiments of the described device and together with the description serve to explain the principles of the described device. Other embodiments of the described device and many of the intended advantages will be readily appreciated as they become better understood by reference to the following detailed description. The elements of the drawings are not necessarily to scale relative to each other. Like reference numerals designate corresponding similar parts.

The described device is explained in more detail below with reference to exemplary embodiments, where:

FIG. 1A shows a plan view of a transistor according to an embodiment of the described device;

FIG. 1B shows another embodiment of a transistor according to the described device;

FIG. 1C shows still a further embodiment of the transistor of the described device;

FIG. 2 shows a flow-chart illustrating the described method;

FIG. 3A shows a cross-sectional view of a substrate when starting the method of the present invention;

FIG. 3B shows a cross-sectional view of the substrate after performing a first etching step;

FIGS. 3C to 3E show several exemplary masks which can be used for defining the structure shown in FIG. 3B;

FIG. 3F shows a cross-sectional view of the substrate after forming a silicon nitride liner;

FIG. 3G shows a cross-sectional view of the substrate after performing a thermal oxidation step;

FIG. 3H shows a cross-sectional view of the substrate after depositing conductive layers constituting the gate electrode;

FIG. 3I shows a perspective view of the completed transistor according to an embodiment of the described device;

FIG. 4A shows a cross-sectional view of the substrate when performing a second embodiment of the described device;

FIG. 4B shows a cross-sectional view of the substrate after performing an etching step;

FIG. 4C shows a cross-sectional view of the substrate after performing a thermal oxidation step;

FIG. 4D shows a cross-sectional view after a further processing step;

FIG. 4E shows a cross-sectional view after forming several conductive layers;

FIG. 4F shows a cross-sectional view of the substrate when performing the described method according to another embodiment;

FIG. 5A shows a layout of an inverter structure;

FIG. 5B shows an exemplary plan view of an inverter structure according to an embodiment of the described device;

FIG. 5C shows a cross-sectional view of a substrate comprising the inverter structure shown in FIG. 5B; and

FIG. 5D shows a further cross-sectional view of the substrate comprising the inverter structure shown in FIG. 5B.

### DETAILED DESCRIPTION

As will be discussed in the following, a semiconductor device comprises a transistor which is formed in an active area forming part of a semiconductor substrate, and isolation trenches, wherein the isolation trenches are adapted to delimit the active area and are filled with an insulating material, the transistor comprising a first source/drain region and a second source/drain region, a channel being formed between the first and the second source/drain regions, a gate electrode formed of a conductive material and a gate insulating layer which is disposed between the gate electrode and the channel, wherein the channel is formed as a ridge in the semiconductor substrate, wherein part of the gate electrode is disposed in a groove arranged between the ridge and the isolation trench, the groove extending to a depth d which is measured from a top surface of the ridge to a bottom surface of the groove, and the isolation trenches extend to a depth x which is measured from a bottom surface of the insulating material to at least the top surface of the ridge, wherein x>d.

Moreover, an inverter which is at least partially formed in a semiconductor substrate comprises a first transistor comprising a first source region connected to a power supply, a first drain region connected to an output terminal, a first channel being formed between the first source and drain regions a first gate electrode adjacent to the first channel, and a first gate insulating layer which is disposed between the first gate electrode and the first channel, a second transistor comprising a second source region connected to a ground, a second drain region connected to the output terminal, a source channel being formed between the second source and drain regions, a second gate electrode adjacent to the channel, and a second gate insulating layer which is disposed between the second gate electrode and the second channel, an input terminal connected to the first and second gate electrodes, wherein each of the first and second transistors are formed as FinFETs, the first and the second channels being ridge shaped, the first and second gate electrode being adjacent to the first and second channels on at least three sides of the corresponding channel, the first gate electrode extending from a top surface of the corresponding ridge to a depth d1 along the first channel and the second gate electrode extending from a top surface of the corresponding ridge to a depth d2 along the second channel, wherein d1>d2.

In addition, a semiconductor device comprises a transistor which is formed in an active area forming part of a semiconductor substrate, and isolation trenches, wherein the isolation trenches are adapted to delimit the active area and are filled with an insulating material, the transistor comprising a first source/drain region and a second source/drain region, a channel being formed between the first and the second source/drain regions, and a component for controlling an electrical current flowing in the channel, wherein the channel is formed as a ridge in the semiconductor substrate, the ridge including a top portion and a bottom portion disposed beneath the top portion, wherein part of the component for controlling an electrical current is disposed in a ridge isolator for isolating the ridge from a corresponding one of the isolation trenches, the ridge isolator extending to a depth d, and the isolation trenches extend to a depth x which is measured from the top portion of the insulating material to at least the top surface of the ridge, wherein x>d.

Moreover, a method of forming a transistor, comprises providing a semiconductor substrate having a surface, defining an active area by providing isolation trenches adjacent to the active area, the isolation trenches being filled with an insulating material, defining isolation grooves in the substrate material, the isolation grooves being adjacent to a portion of the active area in which the channel is to be formed, providing an insulating material in a bottom portion of each of the isolation grooves, providing a gate insulating material on a surface of the channel, providing a gate electrode at least partially in each of the isolation grooves so that the gate electrode is adjacent to the channel, and providing source/drain regions in the active area.

In the followed detailed description reference is made to the accompanying drawings, which form a part hereof and in which is illustrated by way of illustration specific embodiments in which the described device may be practiced. In this regard, directional terminology such as “top”, “bottom”, “front”, “back”, “leading”, “trailing”, etc., is used with reference to the orientation of the Figures being described. Since components of embodiments of the described device can be positioned in a number of different orientations, the directional terminology is used for purposes of illustration and is in no way limiting. It is to be understood that other embodiments may be utilized and structural or logical changes may be made without departing from the scope of the claimed device. The following detailed description, therefore, is not to be taken in a limiting sense, and the scope of the described device is defined by the appended claims.

In the following paragraphs, exemplary embodiments of the device and/or method are described in connection with the figures.

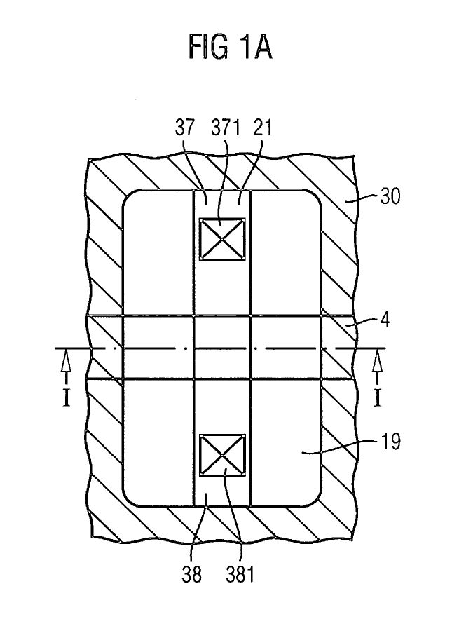

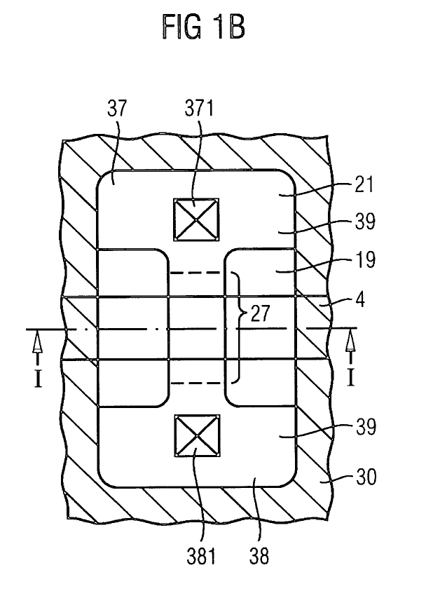

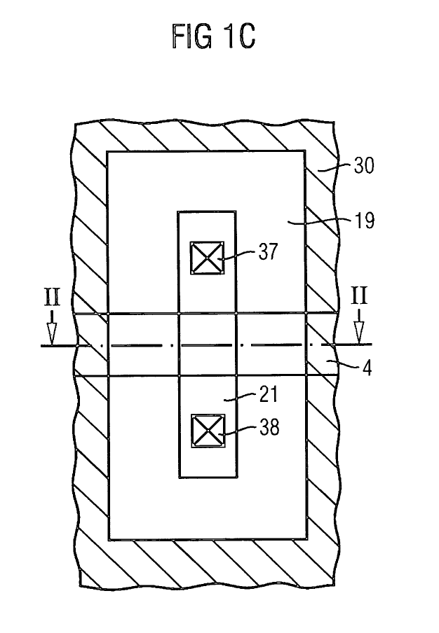

FIG. 1A shows a plan view of an exemplary embodiment of the transistor according to the described device. As can be seen, an active area 21 is delimited by isolation trenches 30. In particular, a first and a second source/drain region are formed in the active area. The first and second source/drain regions 37, 38 may be respectively connected via contact structures 371, 381 to external circuitry. A channel is formed between the first and the second source/drain regions 37, 38. As can further be seen, a gate electrode 4 is disposed adjacent to the channel region. Moreover, fin isolation grooves 19 are formed such that the grooves 19 are in contact with the active areas 21.

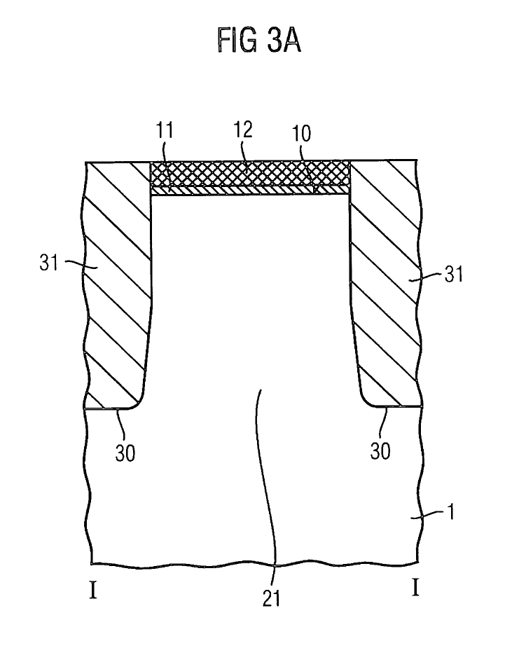

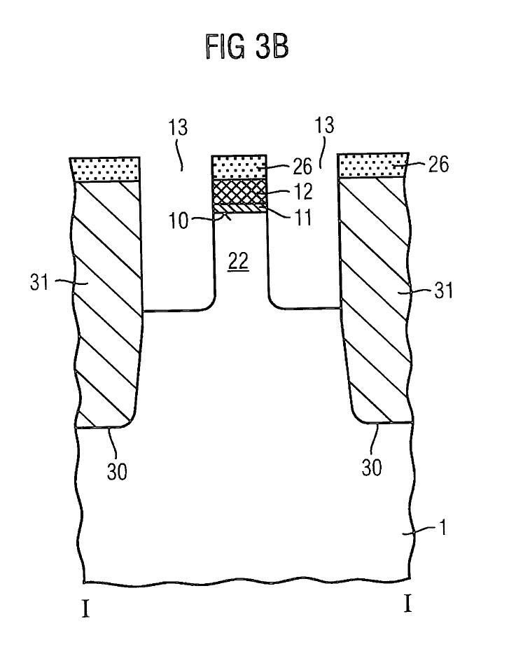

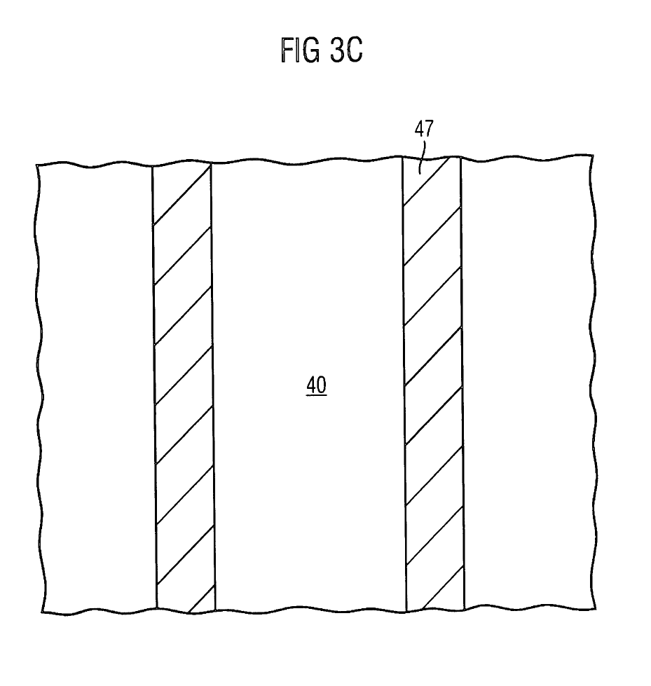

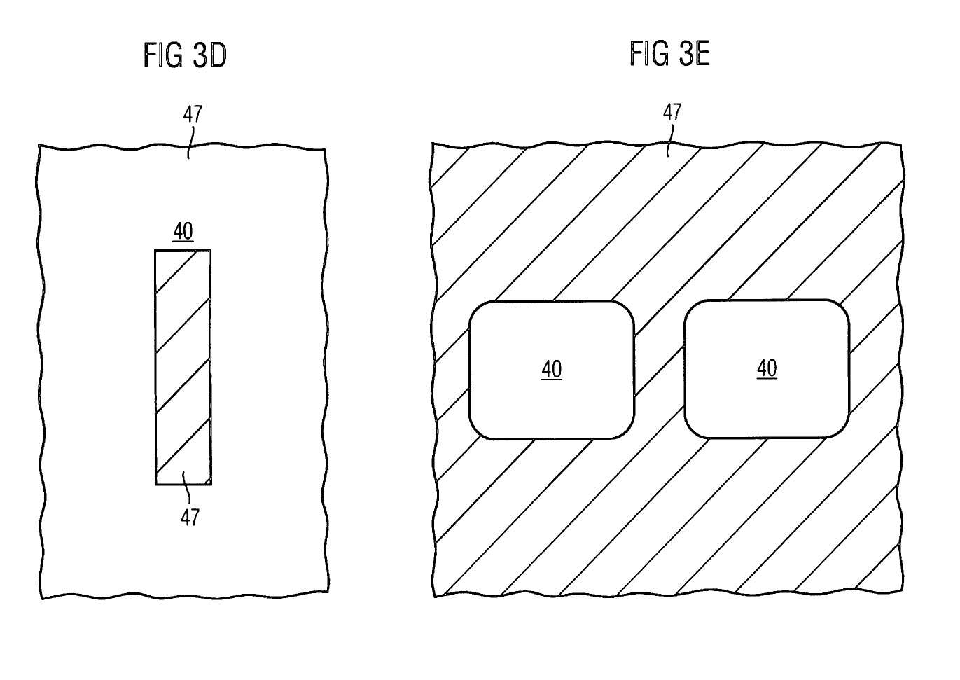

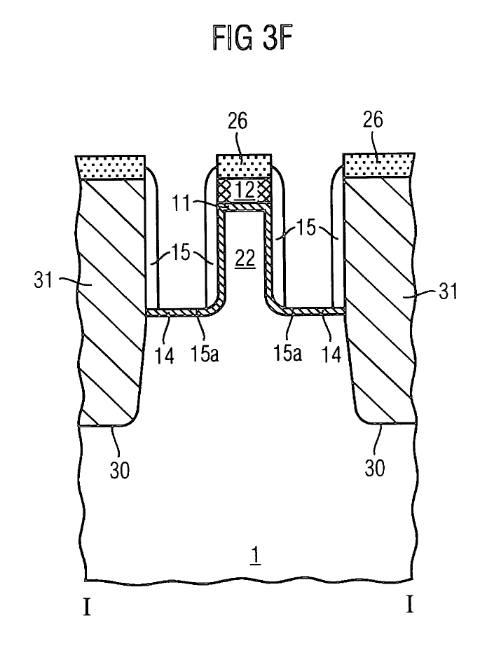

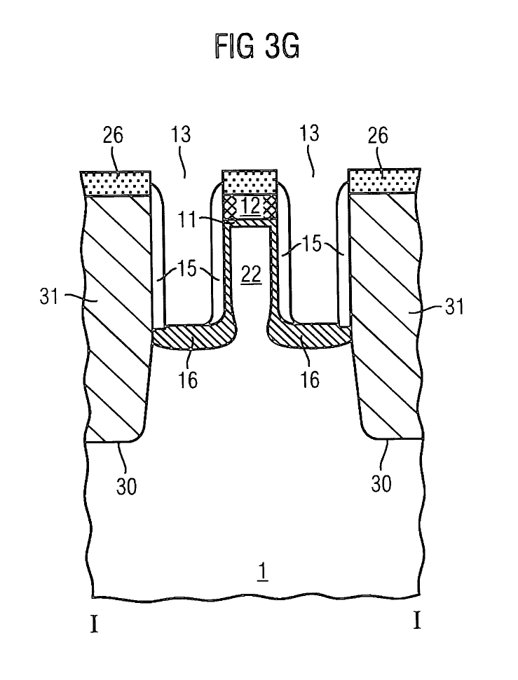

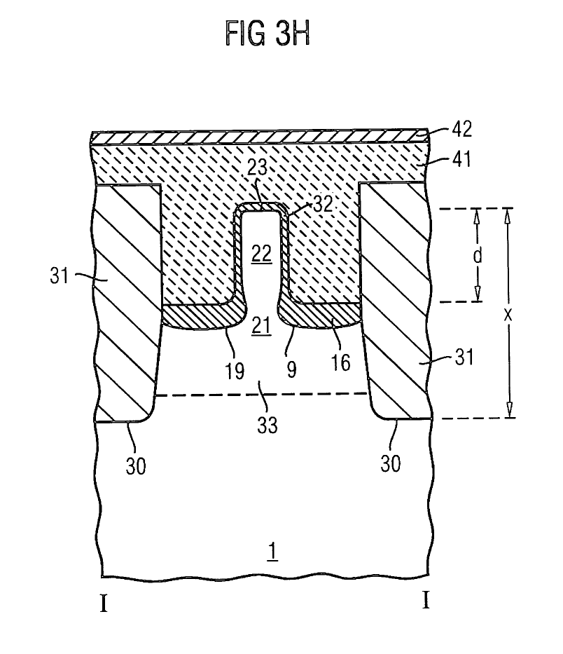

FIG. 3H shows a cross-sectional view of the transistor shown in FIG. 1A, e.g., between I and I. In particular, in a semiconductor substrate 1, such as a silicon substrate, a doped well portion 33 is formed. For example, the doped well portion may be p- or n-doped. Moreover, the silicon substrate may be monocrystalline. For example, such a monocrystalline substrate does not comprise a buried silicon oxide layer. The active area 21 is laterally delimited by isolation trenches 30 which are filled with an insulating filling 31. Moreover, in the upper portion of the substrate, the active area has the shape of a ridge having a top side and two lateral sides. The ridge 22 is laterally delimited by fin isolation grooves 19, wherein the lower portion of the fin isolation groove is filled with an insulating material 16. Moreover, the conductive material 41 of the gate electrode 4 is disposed in these fin isolation grooves 19. As can be taken from FIG. 3H, the isolation trenches 30 extend to a large depth when measured from the top surface 23 of the ridge. For example, the depth x of the isolation trenches may be at least 200 nm, e.g., 250 nm or 300 nm or more. Moreover, the conductive material 41 of the gate electrode 4 extends to a depth d which is measured from the top surface 23 of the ridge to the bottom portion of the conductive material 41. As can be taken from FIG. 3H, d<x. In other words, the isolation trenches 30 extend to a larger depth than the isolation grooves 19.

The transistor may as well be implemented in the manner depicted in FIG. 1B. For example, as is shown in FIG. 1B, the active area 21 has a greater width in the contact area than in the channel portion. In the contact area, the source/drain portions 37, 38 and, in particular, the contact structures 371, 381 are disposed. Accordingly, a contact resistance between the first or second source/drain region 37, 38 and a corresponding contact structure 371, 381 is reduced while setting a desired width of the ridge 22. Moreover, the transistor may as well be implemented in the manner as is shown in FIG. 1C, for example. As can be seen from FIG. 1C, the entire active area 21 is surrounded by the fin isolation groove 19.

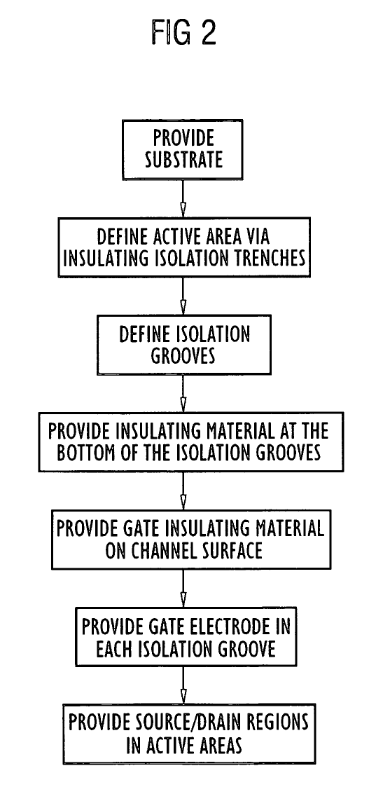

FIG. 2 shows a flow-chart illustrating an embodiment of the method of forming a transistor of the present invention. As is shown, first, a semiconductor substrate such as a monocrystalline silicon substrate is provided (S1). The substrate has a surface. Thereafter, an active area is defined in the semiconductor substrate by forming isolation trenches. The isolation trenches are filled with an insulating material (S2). Then, isolation grooves are defined in the substrate material. The isolation grooves are adjacent to a portion of the active area in which the channel is to be formed (S3). Then, an insulating material is provided in a bottom portion of each of the isolation grooves (S4). A gate insulating material such as silicon dioxide is provided so as to be in contact with the channel (S5). Thereafter, a gate electrode is defined by providing a gate electrode material at least partially in each of the isolation grooves (S6). Then, the source and drain portions of the transistor are defined (S8). As is commonly known, the source and drain portions of the transistor can as well be provided at an earlier or later processing step, as is suitable for the purposes of the described device.

For performing the method according to an embodiment of the described device first, a semiconductor substrate 1 is provided. For example, the substrate may be a monocrystalline silicon substrate. Then, the substrate surface 10 is covered with a thin silicon oxide layer 11, forming the pad oxide layer. The silicon oxide layer may have a thickness of approximately more than 5 or 10 nm. Thereafter, a first hard mask layer 12 is deposited. For example, a silicon nitride layer may be taken as the first hard mask layer. The first hard mask layer may have a thickness of approximately 30 nm or more. Then, as is common, isolation trenches 30 are defined in a substrate. For example, this may be accomplished, by applying a suitable photoresist material and photolithographically patterning the photoresist material so as to define the isolation trenches 30. The pattern of isolation trenches 30 usually depends on the layout of the device to be formed. After photolithographically defining the isolation trenches 30, the first hard mask layer 12 is correspondingly patterned. Taking the patterned hard mask layer 12 as an etching mask, a suitable etching method is performed so as to etch the isolation trenches 30. For example, this may be accomplished by reactive ion etching. Thereafter, the isolation trenches 30 are filled with an insulating material. For example, this may be accomplished by depositing one or more layers and fillings, which may as well comprise different materials. For example, first, an insulating liner such as made of silicon nitride may be deposited, followed by an oxide filling. Thereafter, a CMP (chemical mechanical polishing) step is performed so as to obtain a smooth surface. As a result, the isolation trenches 30 are filled with an insulating material 31. The resulting structure is shown in FIG. 3A which shows a cross-sectional view between I and I as can also be taken from FIGS. 1A, 1B or 1C. As can be seen from FIG. 3A, active areas 21 are formed, the active areas being laterally delimited by isolation trenches 30. For example, the isolation trenches may extend to a depth of more than 200 nm, such as 300 nm or more, this depth being measured from the substrate surface 10.

Thereafter, a ridge 22 is defined in the active area 21, as shown, e.g., in FIG. 3B. For example, a second hard mask may be deposited. The material of the second hard mask is preferably different from the insulating material filled in the isolation trenches 30. For example, the second hard mask may be made of silicon nitride. The second hard mask may have a thickness of approximately 50 nm. Thereafter, a further lithographic step is performed so as to pattern the second hard mask for defining isolation grooves which are adjacent to the ridge 22. For example, FIGS. 3C to 3E show exemplary layouts of the mask which may be used for patterning the isolation grooves 19. For example, as is shown in FIG. 3C, such a mask may comprise mask openings and opaque portions 47. The mask openings 40 may be arranged in a stripe-like manner so that stripes of the second hard mask layer 26 are uncovered after this photolithographic step. In addition, the opaque portions 47 are positioned so as to cover the substrate portions in which the ridge 22 is to be formed. As an alterative, as is shown in FIG. 3D, the masks may be implemented in such a manner, that islands of an opaque material 47 are surrounded by the transparent portions 40. As a consequence, a ridge-like portion of the active area is completely surrounded by a portion in which the second hard mask layer 26 is uncovered. Moreover, as is shown in FIG. 3E, the transparent portions may be formed in a dot-like manner so as to locally expose the second hard mask layer 26. Thereby, for example the layout as shown in FIG. 1B can be obtained.

After correspondingly exposing the photoresist material, predetermined portions of the second hard mask layer 26 are uncovered. Then, an etching step for etching these uncovered portions of the second hard mask layer is performed so as to generate an etching mask. Thereafter, a suitable etching step, for example a reactive ion etching step which selectively etches silicon with respect to silicon oxide is performed so to form the openings 13. As can be seen from FIG. 3B, the openings 13 are adjacent to the ridge-like portion 22 of the active area. The openings 13 extend to a depth which is smaller than the depth of the isolation trenches. For example, each of the openings 13 may extend to a depth more than approximately 100 nm. For example, by adjusting the depth of each of the openings 13, the depth to which the gate electrode extends, can be adjusted. Accordingly, the width of the channel of the resulting transistor can be adjusted. Since it is easier to control the etching depth in a silicon substrate material than in an insulating filling 31, this adjustment is rather precise and accordingly, the width of the channel can accurately be set.

Thereafter, optionally at least one sacrificial silicon oxide layer may be grown and removed. Thereafter, the silicon oxide layer 14 is present so as to cover the silicon surface, as shown, e.g., in FIG. 3F. For example, the silicon oxide layer may have a thickness of 3 to 10 nm. Then, a silicon nitride spacer 15 is formed. For example, this may be accomplished conformally depositing a silicon nitride layer having a thickness of approximately more than 4 nm and for example less than 8 nm and subsequently performing an anisotropic etching step which etches the horizontal portions of the silicon nitride layer while leaving the horizontal portions thereof covered. As a consequence, the sidewalls of the opening 13 are covered with a silicon nitride liner 15, whereas the bottom portion of the opening is covered with a silicon oxide layer 14. In the bottom portion, the surface portion of the silicon oxide layer 14 is exposed.

Thereafter, a thermal oxidation step is performed, whereby a thermal SiO₂ layer is grown. In particular, this oxide layer only grows at the exposed surface portions 15a. As a result, the silicon oxide layer 16 is grown in the bottom portion of each of the openings 13. The grown silicon oxide layer may have a thickness of more than 5 nm, for example more than 10 nm or more than 15 nm. The resulting structure is shown in FIG. 3G.

As can be seen, now, the bottom portion of each of the openings is covered with a thick silicon oxide layer 16. Then, the silicon nitride spacer 15 is removed from the sidewalls, for example, by wet etching. Thereafter, optionally certain doping steps may be performed so as to provide the doped well portion 33 as well as an additional channel doping. Then, the sacrificial oxide layer 11 is removed. Optionally, the steps which have been described with reference to FIGS. 3F and 3G may be repeated so as to obtain a thinner fin.

Thereafter, a gate insulating layer is formed, for example by thermal oxidation. As a result, a gate insulating layer 32 is formed, the gate insulating layer 32 being in contact with the channel region. Thereafter, the materials for forming the gate electrode are deposited. By way of example, a polysilicon layer 41 may be deposited, the polysilicon layer 41 being followed by metal layers 42 and optionally, a hard mask layer (not shown). The resulting structure is shown in FIG. 3H.

As can be seen from FIG. 3H, the thick silicon oxide layer 16 which is present in the bottom portion of each of the gate isolation grooves 19, prevents a current leakage from the fin-like portion of the transistor. Thereafter, the transistor is completed by patterning the layer stack for forming the gate electrode. For example, this may be performed by photolithographically defining the gate electrodes and performing a corresponding etching step, such as anisotropic etching. Moreover, suitable spacers and liners are formed, as is common. For example, the gate electrode 4 may be laterally covered by a spacer. Thereafter, the source/drain portions are defined in a generally known manner. For example, implantation steps for defining the source/drain regions as well as extension regions may be performed.

Thereafter, the whole transistor structure may be covered with any dielectrics, as is common, followed by planarizing steps. Any of the junctions and the gate electrodes may be contacted, as is conventional.

FIG. 3I shows the resulting structure according to an embodiment of the described device without dielectric planarizing layers. As is shown in FIG. 3I, isolation trenches 30 are formed so as to delimit an active area. As can be seen in more detail from this three-dimensional view, the isolation trenches extend in two different directions which are perpendicular to each other so as to completely confine an active area 21. A ridge 22 is formed in the active area. To be more specific, the ridge 22 is formed by defining fin isolation grooves 19 which are filled in a lower portion thereof with an insulation material 16. Moreover, the gate electrode material 41 is disposed in these fin isolation grooves 19. A gate electrode 4 is defined by patterning the gate stack comprising the polysilicon layer 41, the metal layer 42 and the hard mask layer 43. In particular, the gate electrode 4 is patterned so as to form stripes which extend from the right hand portion of the drawing to the left hand portion. Moreover, a spacer 36 is disposed adjacent to the gate electrode 4. In the shown embodiment, the n⁺ doped portion 441 is provided in the active area 21 adjacent to the substrate surface. A source/drain extension portion 48 which is made of n-doped silicon is disposed between n⁺ doped portion 441 and the channel portion 27. As can be seen, the isolation trenches 30 extend to a deeper depth, whereas the fin isolation grooves 19 extend to a lesser depth. Moreover, the lower portion of the substrate material is an n-doped portion 331, the p-doped portion 332 being embedded in this n-doped portion 331.

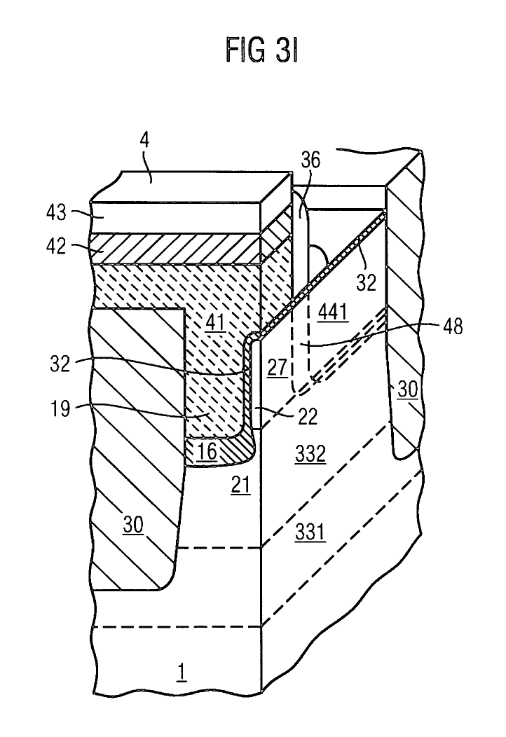

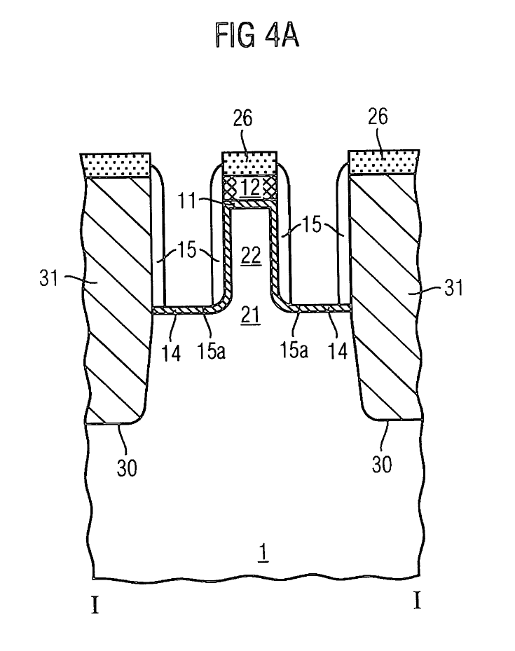

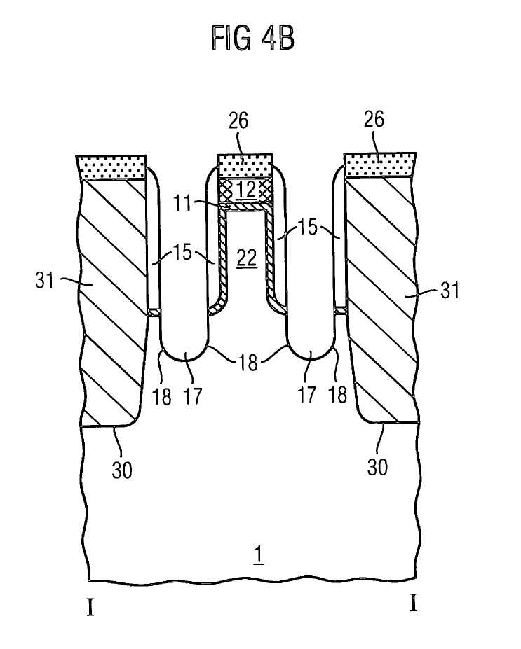

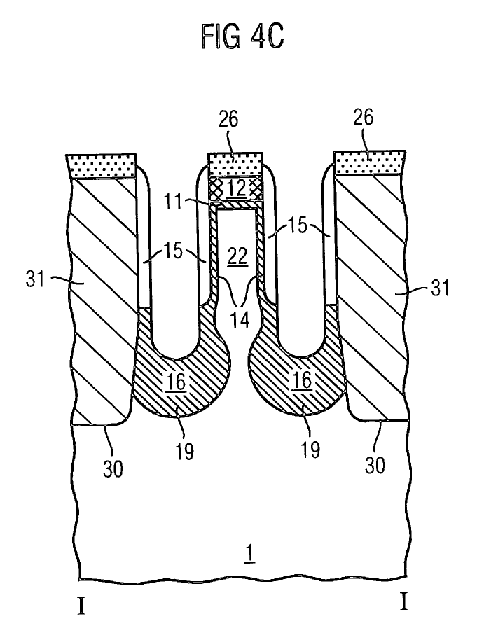

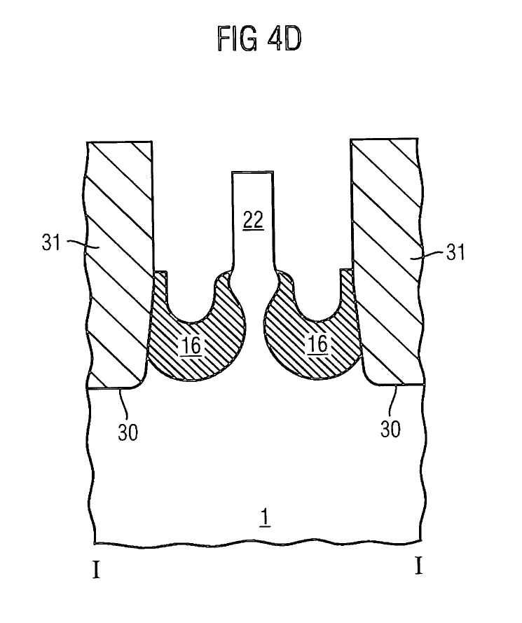

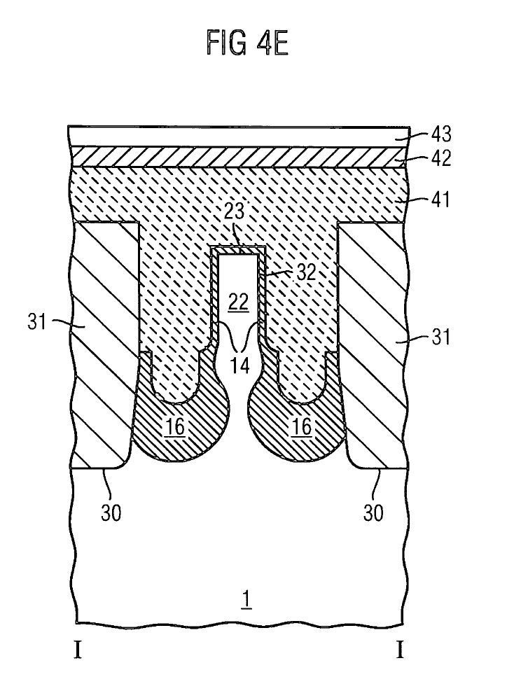

According to a further embodiment of the described device, the fin isolation grooves 19 may be formed by a modified processing sequence. The starting point for performing this embodiment is the structure shown in FIG. 4A which corresponds to the structure shown in FIG. 3F. In other words, the present embodiment comprises the steps which have been described above with reference to FIGS. 3A-3F. Hence, a detailed description of these steps which may be performed in order to obtain the structure shown in FIG. 4A is omitted. As can be seen, in FIG. 4A, the surface of the openings 13 is covered with the silicon dioxide layer 14. In the sidewall portions of each of the active areas 21, the silicon dioxide layer 14 is covered with the silicon nitride spacer 15.

In a subsequent step, an extended opening 17 is formed at the bottom portion of each of the openings 13. To this end, first, an etching step for etching silicon dioxide selectively with respect to silicon nitride is performed, followed by a silicon etching step. In particular, these etching steps may be reactive ion etching steps. As a result, an extended opening 17 having exposed the sidewalls 18 as formed. The resulting structure is shown FIG. 4B.

As can be seen, the bottom portion of each of the extended openings 17 extends to a deeper depth than the bottom portion of the silicon dioxide layer 14 and the silicon nitride spacer 15. In a subsequent step, a thermal oxidation step is performed so as to form a thermal oxide 16 in the bottom portion of each of the openings 13. In particular, since the sidewall portions 18 have been exposed in the previous step, now a thicker silicon dioxide layer 16 can be grown. For example, the silicon dioxide material can have a thickness of approximately 40 to 60 nm.

As an alternative, the silicon dioxide layer 16 may be provided by a selective oxide deposition method followed by a thermal oxidation step. For example, in such a selective oxide deposition method, a silicon dioxide layer is only deposited on a silicon surface. For example, such a method may be a chemical vapor deposition method using for example, TEOS (tetraethylorthosilicate), OMTC (octamethylcyclotetrasiloxan) or HMDS (hexamethyldisiloxan) with added ozone as a precursor. Such an ozone-activated deposition method deposits silicon dioxide on silicon surfaces only. After depositing the silicon dioxide layer 16, a thermal oxidation step is performed so as to react with the surface portion of the silicon substrate 1. Due to these process steps the advantage is obtained that a silicon oxide layer 16 having less strain and stress is formed.

The resulting structure is shown in FIG. 4C. As can be seen, adjacent active regions 21 are isolated from each other by a fin isolation groove 19 having a thick silicon dioxide layer in the bottom portion thereof. After defining and filling the fin isolation grooves 19, the silicon nitride layers 12, 15 are removed, for example by wet etching. Thereafter, optionally, implantation steps for providing certain well and/or channel dopings may be performed. Thereafter, the silicon dioxide layer 14 is removed from the surface. Optionally, further thermal oxidation steps may be performed, followed by a step of removing the grown oxide layer, so as to obtain a thinner active region 21. For example a sacrificial layer (not shown) having a thickness of approximately 3 nm may be grown and removed. Thereby, in addition, crystal damages are removed.

As a result, the structure shown in FIG. 4D is obtained. As can be seen, adjacent active regions 21 having the shape of a ridge are isolated from each other by fin isolation grooves which are filled with an insulating material in the bottom part thereof. In the next steps, a gate oxide layer 32 is provided as is conventional. Thereafter, the gate stack is deposited. For example, the gate stack may comprise a bottom polysilicon layer 41, followed by the metal layer or metal layer stack 42 and a cap layer 43, for example a silicon nitride cap layer. Thereafter, the gate electrode is patterned in a manner as is conventional. Moreover, the doped portions are provided so as to define the first and second source/drain regions.

A cross-sectional view of the resulting structure is shown in FIG. 4E. As is shown in FIG. 4E, according to the present embodiment, the thickness of the silicon dioxide layer 16 filling the bottom portion of the fin isolation grooves is very thick when compared with the depth of the fin isolation grooves 19. In particular, the distance di from the upper surface of the ridges to the top surface of the silicon dioxide layer is at least 0.5×dg, wherein dg denotes the distance from the upper surface of each of the ridges to the bottom side of the fin isolation groove 19. Moreover, the distance di is less than 0.7×dg.

According to still a further embodiment of the described device, the steps which have been described with reference to FIGS. 4A to 4D are performed. Starting from the structure shown in FIG. 4D, an annealing step is performed in hydrogen. In particular, this annealing step is performed at a temperature of approximately 800° C. for typically one minute. As a result, the upper edges of an active region 21 are shaped so as to have a round or circular form. In particular, as a result of minimizing the surface energy, during this annealing step, the silicon material is rounded so as to obtain active regions 21 having a rounded or circular cross-section.

The resulting structure is shown in FIG. 4F. As can be seen, the active regions 21 have a rounded or circular shape in the upper portion thereof. Moreover, adjacent active regions 21 are isolated from each other by a fin isolation groove 19 which is filled with an insulating material 16 in the bottom portion thereof. In the next step, the usual process steps for completing a transistor are performed. In particular, a gate insulating layer 32 and a gate electrode 4 are formed as is conventional.

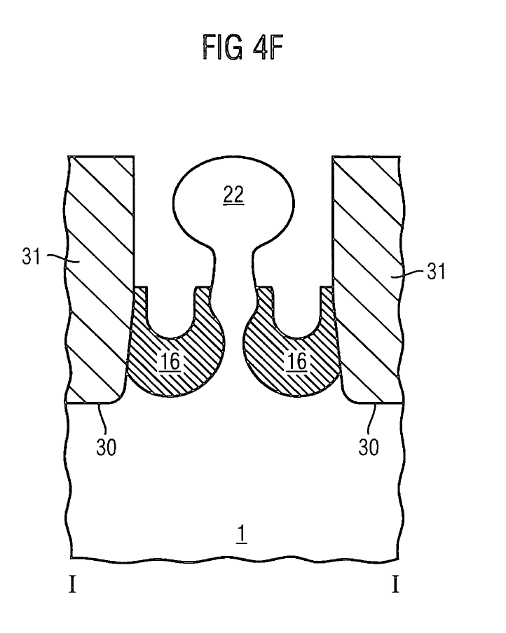

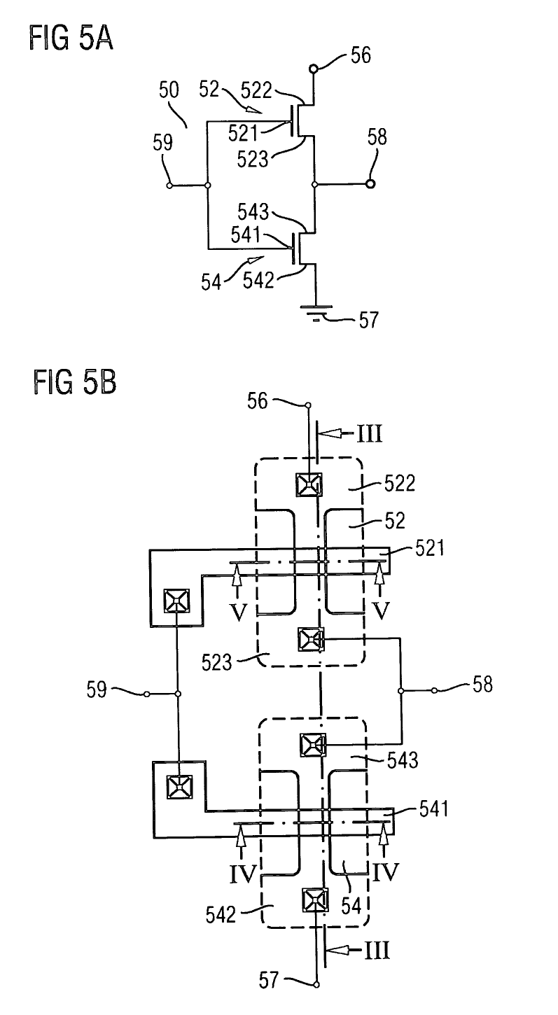

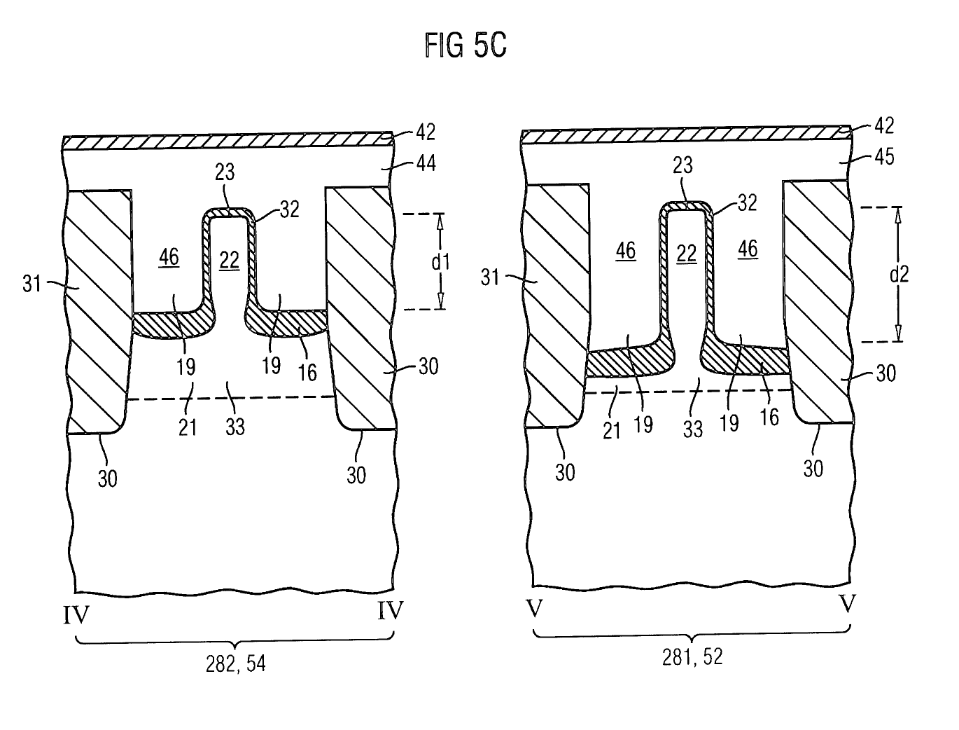

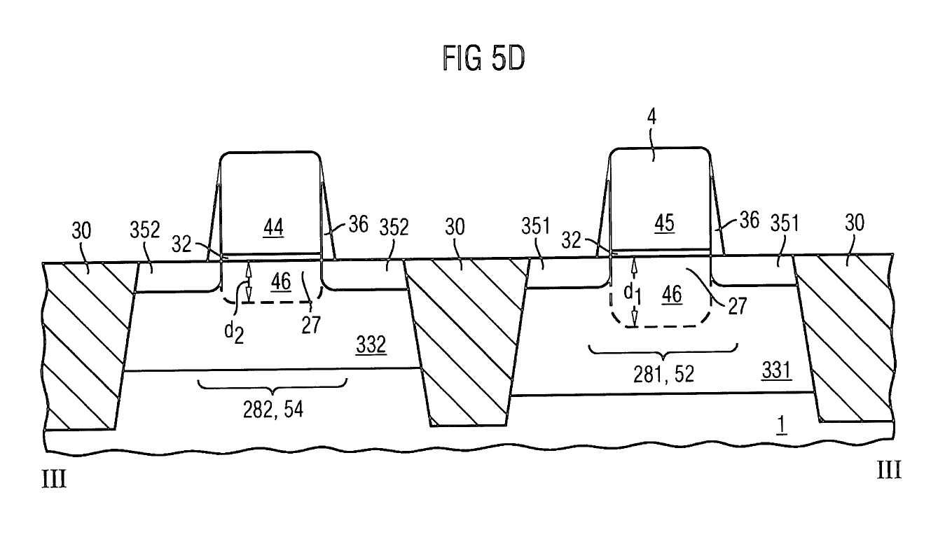

As will be described in the following, the transistor of the present invention can be used in an inverter structure. As is generally known, an inverter structure comprises a complementary pair of transistors, i.e., an n-channel transistor comprising n-type source/drain regions, and a p-channel transistor comprising p-type source/drain regions. FIG. 5A illustrates a schematic layout of such an inverter structure. In particular, the source portion 522 of the PMOS transistor 52 is connected with a power supply 56. Moreover, the drain portions 523 and 543 of the PMOS transistor 52 and the NMOS transistor 54, respectively, are connected with the output terminal 58. The source portion 542 of the NMOS transistor 54 is connected to ground 57. The gate electrodes 521 and 541 of each of the PMOS transistor 52 and the NMOS transistor 54 are connected with the input terminal 59.

FIG. 5B shows an implementation of such an inverter structure. As can be seen, each of the PMOS and NMOS transistors 52 and 54 is implemented in the manner as has been described with reference to FIG. 3I. In particular, the transistor is formed in a semiconductor substrate, in particular, a monocrystalline semiconductor substrate which may be made of silicon. For example, this substrate does not comprise a buried silicon oxide layer. The active area of each of the transistors has the form of a ridge so that the gate electrodes 521, 541 enclose the channel at three sides thereof. The gate electrodes 521, 541 are insulated from the channels of the corresponding transistors 52, 54 by a gate insulating layer 33. As is shown in FIG. 5B, the active areas forming part of the PMOS and the NMOS transistors 52, 54 may be formed in isolated ridges. Nevertheless as is obvious to the person skilled in the art, they may as well be implemented in a common ridge or active area. As is generally known, the channel width of a PMOS transistor should be increased with respect to the channel width of an NMOS transistor, in order to obtain similar resistances in each of the channels, taking into account the reduced mobility of holes with respect to the mobility of electrons. According to the described device, this can be accomplished by implementing the PMOS transistor in such a manner, that the plate-like portions of the gate electrode 521 extend to a deeper depth than the plate-like portions of the gate electrode 541 of the NMOS transistor. Accordingly FIG. 5C illustrates a cross-sectional view of the transistors 52 and 54 which is taken between IV and IV and between V and V respectively.

As can be seen, each of the transistors has a structure which is similar to the structure shown in FIG. 3I. As can be seen from FIG. 5C, each of the transistors is formed in an active area 21. In the shown cross-section, the active area has the shape of a ridge 22 comprising a top portion and two sidewall portions. The active areas 21 are laterally confined by isolation trenches 30 which are filled with an insulating material 31. The upper portion of the active area 21 is doped and forms a doped well portion. To be more specific, the doped well portion 33 of the transistor 281 is n-doped, whereas the doped well portion 33 of the transistor 282 is p-doped. Each of the ridges 22 is laterally confined by a fin isolation groove 19. The lower portion of each of the fin isolation grooves 19 is filled with an insulating material, for example, silicon oxide. Moreover, a gate electrode material is disposed in the upper portion of each of the fin isolation grooves 19. As can be seen from the transistor 281, the plate-like portion 46 of the transistor extends to a depth d2 which is measured from the top surface 23 of the ridge 22 to the bottom portion of the conductive material of the gate electrode. Moreover, as can be seen from the left hand portion of FIG. 5C, the gate electrode of the transistor 282 extends to a depth d1, this depth being measured from the top surface 23 of the ridge 22 to the bottom side of the conductive material of the gate electrode 4. In addition, as can be taken from FIG. 5C, d1<d2. If the transistor 281 as well as the transistor 282 is formed in one single ridge, the depth d1 and d2 are both measured from the top surface 23 of the common ridge 22. If the transistor 281 and the transistor 282 are formed in different ridges, respectively, the depth d1 and d2 are measured from the top surface 23 of the ridge 22 in which the channel of the corresponding transistor is formed. Due to the special manufacturing method, which has been described above, it is possible to exactly adjust the depth to which the gate electrode material extends in each of the transistors. Thereby, the resistance of the transistor can be exactly adjusted.

In the embodiment shown in FIG. 5C, the material of the gate electrode for controlling the conductivity of the PMOS transistor may be made of n⁺ doped polysilicon. Moreover, the conductive material of the gate electrode of the NMOS transistor 282 shown in the left hand portion may be made of p⁺ doped polysilicon. Thereby, the threshold voltage of the respective transistors can be set to a higher value. Usually, the threshold voltage of a FinFET is lowered by approximately 1 V due to the full depletion of the channel. Nevertheless, when such a FinFET is implemented in an inverter structure as shown in FIG. 5A, for example, it is desirable to have a threshold voltage which is higher than 0 V. Accordingly, by selecting a gate material having a higher work function the threshold voltage of the resulting transistor can be raised. Accordingly in case of a PMOS transistor comprising an n-doped well portion, an n⁺ doped gate electrode material, is advantageous, whereas in an NMOS transistor comprising a p-doped well portion, a p⁺ doped gate material is advantageous.

Moreover, FIG. 5D shows a cross-sectional between III and III, as can be taken from FIG. 5B, for example. In the cross-sectional view shown in FIG. 5D, the first transistor 281 and the second transistor 282 are arranged side by side, the transistors being insulated from each other by isolation trenches 30 which are filled with an insulating material. In the transistor 281 which is implemented as a PMOS transistor, the doped well portion 331 is n-doped. The n-doped well portion 331 extends to a deeper depth than the p-doped well portion 332 of the NMOS transistor 282. In addition, doped source and drain portions 351 are provided adjacent to the substrate surface. A gate electrode 4 is provided and controls the conductivity of the channel 27 which is formed between the source and the drain portions 351. The gate electrode is insulated from the channel 27 by a gate insulating layer 32. The first gate electrode of the PMOS transistor 281 may be made of n⁺ doped polysilicon 45. The second gate electrode of the NMOS transistor 282 may be made of p⁺ doped polysilicon 44. The gate electrode 4 further comprises plate-like portions 46 which extend in a plane lying before and behind the illustrated plane of the drawing. Likewise the NMOS transistor 282 comprises source and drain portions 352. A channel 27 is formed in the left-hand transistor. The conductivity of the channel 27 is controlled by the gate electrode 4. In the shown embodiment, the material constituting the gate electrodes is different in both transistors. Moreover, the isolation trenches extend to a deep depth, for example more than 200 nm. Accordingly, an influence of neighboring transistors is reduced, so that, as a consequence, a higher packaging density of the transistors can be implemented. In the embodiment shown in FIG. 5D both transistors are formed in one portion of the substrate. Nevertheless, it is obvious to the person skilled in the art, that the scope of the described device encompasses any arbitrary configuration comprising two complementary transistors which are formed as FinFETs in which the gate electrodes comprise plate-like portions 46, respectively, the plate-like portion extending to a larger depth for the PMOS transistor than for the NMOS transistor.

While the device and method have been described in detail with reference to specific embodiments thereof, it will be apparent to one of ordinary skill in the art that various changes and modifications can be made therein without departing from the spirit and scope thereof. Accordingly, it is intended that the described device and method cover the modifications and variations of this device and method provided they come within the scope of the appended claims and their equivalents.

What is claimed is:

1. A semiconductor device comprising:
a transistor disposed in an active area of a semiconductor substrate, the transistor comprising: a first source/drain region, a second source/drain region, a channel formed between the first and the second source/drain regions, a gate electrode formed of a conductive material, and a gate insulating layer disposed between the gate electrode and the channel; and
isolation trenches, wherein the isolation trenches are adapted to delimit the active area and are filled with an insulating material;
wherein the channel is formed as a ridge in the semiconductor substrate, wherein part of the gate electrode is disposed in a groove arranged between the ridge and the isolation trench, the groove extending to a groove depth measured from a top surface of the ridge to a bottom surface of the groove;
wherein the isolation trenches extend to an isolation trench depth measured from a bottom surface of the insulating material to at least the top surface of the ridge, wherein the isolation trench depth is greater than the groove depth.

2. The semiconductor device of claim 1, wherein the ridge has a greater width in at least one of the first and second source/drain regions than in a channel region, the width being measured in a direction perpendicular to a line connecting the first and second source/drain regions.

3. The semiconductor device of claim 1, wherein the substrate is a monocrystalline silicon substrate.

4. The semiconductor device of claim 1, wherein the isolation trench depth is at least 200 nm.

5. The semiconductor device of claim 1, further comprising an insulating material filling the lower portion of the grooves.

6. An inverter at least partially formed in a semiconductor substrate, the inverter comprising:
a first transistor comprising a first source region connected to a power supply, a first drain region connected to an output terminal, a first channel formed between the first source and drain regions, a first gate electrode adjacent to the first channel, and a first gate insulating layer disposed between the first gate electrode and the first channel;
a second transistor comprising a second source region connected to a ground, a second drain region connected to the output terminal, a second channel formed between the second source and drain regions, a second gate electrode adjacent to the second channel, and a second gate insulating layer disposed between the second gate electrode and the second channel; and
an input terminal connected to the first and second gate electrodes, wherein each of the first and second transistors comprises a FinFET, the first and the second channels being ridge shaped, the first and second gate electrodes being adjacent to the first and second channels on at least three sides of the corresponding channel, the first gate electrode extending from a top surface of the first channel ridge to a first gate electrode depth measured along the first channel and the second gate electrode extending from a top surface of the second channel ridge to a second gate electrode depth measured along the second channel, wherein the first gate electrode depth is less than the second gate electrode depth.

7. The inverter of claim 6, wherein the first and the second transistor are formed in a single active area.

8. The inverter of claim 6, wherein the substrate is a monocrystalline silicon substrate.

9. The inverter of claim 6, further comprising:
isolation trenches filled with an insulating material disposed between adjacent transistors.

10. The inverter of claim 6, further comprising:
first grooves arranged adjacent to the first channel; and
second grooves arranged adjacent to the second channel;
wherein part of the first gate electrode is disposed in the first grooves and part of the second gate electrode is disposed in the second grooves.

11. The inverter of claim 10, further comprising:
an insulating material filling the lower portion of each of the first and second grooves.

12. The inverter of claim 11,
wherein the first groove extends from the substrate surface to a first groove depth and the second groove extends from the substrate surface to a second groove depth, the first groove depth being less than the second groove depth.

13. The inverter of claim 12,
wherein each of the first and second transistors is formed with an active area in the semiconductor substrate, the active area being delimited via isolation trenches filled with an insulating material;
wherein the isolation trenches extend to an isolation trench depth measured from a bottom surface of the insulating material to at least the top surface of the ridge, the isolation trench depth being greater than both the first groove depth and the second groove depth.

14. The inverter of claim 6, wherein the first gate electrode comprises a semiconductor material with a first conductivity type and the second gate electrode comprises a semiconductor material with a second conductivity type that is different from the first conductivity type.

15. The inverter of claim 14, wherein the material of the first gate electrode is n⁺ doped, whereas the material of the second gate electrode is p⁺ doped.

16. A semiconductor device comprising,
a transistor disposed in an active area of a semiconductor substrate, the transistor comprising: a first source/drain region, a second source/drain region, a channel being formed between the first and the second source/drain regions, and means for controlling an electrical current flowing in the channel; and
isolation trenches, wherein the isolation trenches are adapted to delimit the active area and are filled with an insulating material;
wherein the channel is formed as a ridge in the semiconductor substrate, the ridge including a top portion and a bottom portion disposed beneath the top portion, wherein part of the means for controlling an electrical current is disposed in a ridge isolator for isolating the ridge from a corresponding one of the isolation trenches, the ridge isolator extending to a ridge isolator depth;
wherein the isolation trenches extend to an isolation trench depth measured from a bottom surface of the insulating material to at least the top surface of the ridge, wherein the isolation trench depth is greater than the ridge isolator depth.

17. A method of forming a transistor, comprising:
providing a semiconductor substrate including a surface;
defining an active area via providing isolation trenches adjacent to the active area, the isolation trenches being filled with an insulating material;
defining isolation grooves in the substrate material such that a channel is formed in the active area between the adjacent isolation grooves;
providing an insulating material in a bottom portion of each of the isolation grooves;
providing a gate insulating material on a surface of the channel;
providing a gate electrode at least partially disposed in each of the isolation grooves such that the gate electrode is adjacent to the channel; and
providing source/drain regions in the active area.

18. The method of claim 17, wherein defining isolation grooves comprises selectively etching the substrate material with respect to the insulating material of the isolation trenches.

19. The method of claim 17, wherein the isolation trenches are formed to extend to an isolation trench depth and the isolation grooves are formed to extend to an isolation groove depth, wherein the isolation trench depth is measured from a bottom surface of the insulating material to at least a top surface of the active area and the isolation groove depth is measured from a bottom surface of the isolation groove to the top surface of the active area, wherein the isolation trench depth is greater than the isolation groove depth.
